(19) United States
(12) Patent Application Publication
(10) Pub. No.: US 2025/0306095 A1
(43) Pub. Date: Oct. 2, 2025

(54) HIGH PERFORMANCE TEST INTERFACES FOR SEMICONDUCTOR DEVICES

(71) Applicant: Intel Corporation, Santa Clara, CA (US)

(72) Inventors: R Selvakumar RAJAGOPAL, Tapah (MY); Suketu BHATT, Folsom, CA (US); Shelby G. ROLLINS, Hillsboro, OR (US); Shivaprashant BULUSU, Bengaluru (IN); Ronald SWARTZ, Granite Bay, CA (US); Daniel CAMACHO MONTEJO, El Dorado Hills, CA (US); Oscar MENDOZA, Shrewsbury, MA (US)

(21) Appl. No.: 18/622,573

(22) Filed: Mar. 29, 2024

(51) Int. Cl. G01R 31/317; G01R 31/28

(52) U.S. Cl. CPC G01R 31/31704; G01R 31/2896; G01R 31/31708; G01R 31/31725

(57) ABSTRACT

Semiconductor devices having design for test interfaces are provided. The semiconductor devices can be tested in a manufacturing environment as either a die or a packaged die. The design for test interface comprises a physical layer having transmitter, receiver, and a common lane. The design for test interface also comprises test port interface logic that can interface with the semiconductor device logic. Test port interface logic can include 1:N de-serializer logic, 1:N CLK divider logic, and N:1 serializer logic.

### FIELD

Descriptions are generally related to integrated circuit devices, the testing of integrated circuit devices, and the connections between testing unit and interconnect circuit devices.

### BACKGROUND

Integrated circuit (IC) devices are central to intelligent devices and systems, such as personal computers, laptops, tablets, phones, servers, and other consumer and industrial products and systems. Manufacturing integrated circuit devices presents a number of challenges, and these challenges are amplified as IC devices become smaller, the number of transistors grows, and performance demands increase. The testing and analysis of IC devices are an essential part of the manufacturing process.

Requirements governing the design of physical mechanisms to deliver test content to a device under test (DUT) are a challenge due to the growth in transistor count as lithography advances occur. Traditionally most test access for IC devices such as, application-specific integrated circuits (ASICs), has been through the Joint Action Test Group (JTAG) Institute of Electrical and Electronics Engineers (IEEE 1149.1) standard. This standard's narrow pin count (one IO (input output) for data in and one IO for data out) and low data rate (typically not faster than 100 MHz) has limited the rate of transfer of test content and impacted test cost affordability at scale. These test ports can consume a cost prohibitive number of package pins, can fail to scale up in bandwidth, and can impact design performance on other device features. Design paradigm shifts related to die disaggregation along with ever increasing test content volumes have resulted in older test-port-based designs having high complexity networks, whether on-chip or on-package, to connect the production test system interfaces during high volume manufacturing processes.

### BRIEF DESCRIPTION OF THE DRAWINGS

The figures are provided to aid in understanding the disclosure. The figures can include diagrams and illustrations of exemplary structures, assemblies, data, methods, and systems. For ease of explanation and understanding, these structures, assemblies, data, methods, and systems, the figures are not an exhaustively detailed description. The figures therefore should not be understood to depict the entire metes and bounds of structures, assemblies, data, methods, and systems possible without departing from the scope of the disclosure. Additionally, features are not necessarily illustrated relatively to scale due in part to the small sizes of some features and the desire for clarity of explanation in the figures.

FIG. 1 illustrates an architecture for design for test (DFT) features on a semiconductor device.

FIG. 2 shows a semiconductor package that is coupled to a board and a semiconductor device testing system.

FIG. 3 illustrates a semiconductor device that is coupled to a board and a semiconductor device testing unit.

FIG. 4 provides example test interface waveforms for the operation of a DFT interface on a semiconductor chip.

FIG. 5 illustrates a semiconductor chip having a DFT interface.

FIG. 6 provides a method for testing a semiconductor device using a DFT interface.

FIG. 7 provides an exemplary computing system.

Descriptions of certain details and implementations follow, including non-limiting descriptions of the figures, which depict some examples and implementations.

### DETAILED DESCRIPTION

References to one or more examples are to be understood as describing a particular feature, structure, or characteristic included in at least one implementation. The phrases “one example” or “an example” are not necessarily all referring to the same example or embodiment. Any aspect described herein can potentially be combined with any other aspect or similar aspect described herein, regardless of whether the aspects are described with respect to the same figure or element.

The words “connected” and/or “coupled” can indicate that two or more elements are in direct physical or electrical contact with each other. The term “coupled,” however, can also mean that two or more elements are not in direct contact with each other and are instead separated by one or more elements but they may still co-operate or interact with each other, for example, physically, magnetically, or electrically.

The words “first,” “second,” and the like, do not indicate order, quantity, or importance, but rather are used to distinguish one element from another. The words “a” and “an” herein do not indicate a limitation of quantity, but rather denote the presence of at least one of the referenced items. The terms “follow” or “after” can indicate immediately following or following some other event or events. Other sequences of operations can also be performed according to alternative embodiments. Furthermore, additional operations may be added or removed depending on the application.

Disjunctive language such as the phrase “at least one of X, Y, or Z,” is used in general to indicate that an element or feature, may be either X, Y, or Z, or any combination thereof (e.g., X, Y, and/or Z). Thus, this disjunctive language should be understood not to imply that certain embodiments require at least one of X, at least one of Y, or at least one of Z to each be present.

Flow diagrams as illustrated herein provide examples of sequences of various process actions. The flow diagrams can indicate operations to be executed by a software or firmware routine and/or physical operations. Operations can be performed by semiconductor testing system. Although shown in a particular sequence or order, unless otherwise specified, the order of the actions can be modified. Thus, the illustrated diagrams should be understood only as examples, and the process can be performed in a different order, and some actions can be performed in parallel. Additionally, one or more actions can be omitted and not all implementations will perform all actions.

Various components described can be a means for performing the operations or functions described. Each component described can include software, hardware, or a combination of these. Some components can be implemented as software modules, hardware modules, special-purpose hardware (for example, application specific hardware, application specific integrated circuits (ASICs), and digital signal processors (DSPs)), embedded controllers, or hardwired circuitry).

To the extent various computer operations or functions are described herein, they can be described or defined as software code, instructions, configuration, and/or data. The software content can be provided via an article of manufacture with the content stored thereon, or via a method of operating a communication interface to send data via the communication interface. A machine-readable storage medium can cause a machine to perform the functions or operations described. A machine-readable storage medium includes any mechanism that stores information in a tangible form accessible by a machine (e.g., computing device), such as recordable/non-recordable media (e.g., read only memory (ROM), random access memory (RAM), magnetic disk storage media, optical storage media, flash memory devices). Instructions can be stored on the machine-readable storage medium in a non-transitory form. A communication interface includes any mechanism that interfaces to, for example, a hardwired, wireless, or optical medium to communicate to another device, such as, for example, a memory bus interface, a processor bus interface, an Internet connection, a disk controller.

Terms such as chip, die, IC (integrated circuit) chip, IC die, IC device, microelectronic chip, microelectronic die, semiconductor die, semiconductor device, and/or semiconductor chip are interchangeable and refer to a semiconductor device comprising integrated circuits.

Semiconductor chip manufacturing processes are sometimes divided into front end of the line (FEOL) processes and back end of the line (BEOL) processes. Electronic circuits and active and passive devices within the chip, such as for example, transistors, capacitors, resistors, and/or memory cells, are manufactured in what can be referred to as FEOL processes. Memory cells include, for example, electronic circuits for random access memory (RAM), such as static RAM (sRAM), dynamic RAM (DRAM), read only memory (ROM), non-volatile memory, and/or flash memory. FEOL processes can be, for example, complementary metal-oxide semiconductor (CMOS) processes. BEOL processes include metallization of the chip where interconnects are formed in layers and the feature size of the interconnect increases in layers nearer the surface of the semiconductor chip. Interconnects in, for example, semiconductor chips that are integrated into heterogeneous packages (such as, for example, packages that include memory and logic chips), can also include through silicon vias (TSVs) that transverse the semiconductor chip device region. Semiconductor devices that have TSVs can blur distinctions between BEOL and FEOL processes.

The terms “package,” “packaging,” “IC package,” or “chip package,” “microelectronics package,” or “semiconductor chip package” are interchangeable and generally refer to an enclosed carrier of one or more dies, in which the dies are attached to a package substrate and encapsulated. The package substrate provides electrical interconnects between the die(s) and/or other dies and/or a motherboard or other printed circuit board for IO (input output) communication and power delivery. A package with multiple dies can, for example, be a system in a package.

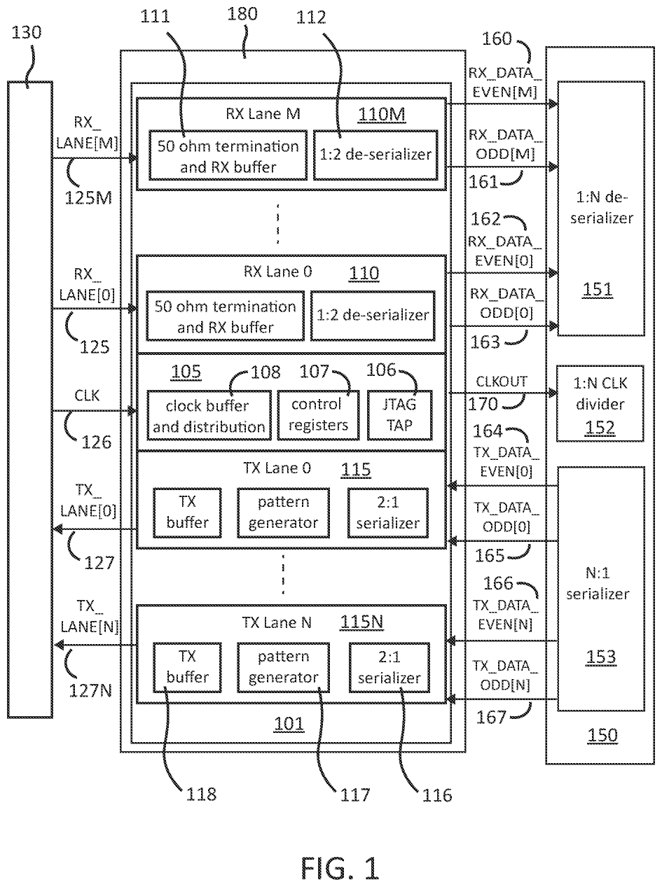

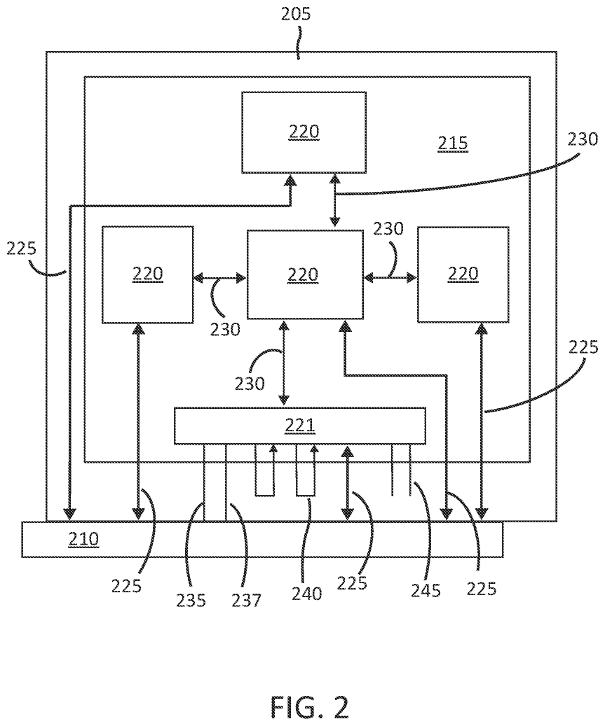

FIG. 1 provides an exemplary design for test (DFT) interface for a semiconductor device. The semiconductor device includes logic for performing one or more computing functions and can be any of the semiconductor devices described herein, for example, with respect to FIGS. 2, 5, and 7. The test port physical layer (PHY) 101 includes a common lane 105, one or more RX (receiver) 110 to 110M, and one or more TX (transmitter) lanes 115 to 115N. The number of RX and TX lanes is adjustable (user selected), 1 to M and 1 to N, respectively, and the number can be selected, for example, by the bandwidth requirement of a given semiconductor device. A smaller semiconductor device may need fewer lanes than a larger semiconductor device. The number of RX lanes 110 to 110M can be different from the number of TX lanes 115 to 115N. The common lane 105 consists of JTAG test access port (TAP) logic 106, physical layer (PHY) control registers 107, and a clock (CLK) buffer logic and distribution network logic 108. The PHY control registers 107 can be accessed through a secondary TAP through a semiconductor-device level TAP network. There are other pins of the test port PHY that are exposed to internal semiconductor device to manage and/or program. These pins include a reset pin, in which the tester can program through the semiconductor-device level TAP network before the mission mode and/or self-test is started. Test port registers through JTAG (control register 107) can be used to program the test port either in mission mode or for self-test using, for example, a pattern generator 117, and can be used to program register settings to achieve a termination resistance (e.g., 50 Ohms, although other values are possible).

Each RX lane 110 to 110M can include a termination resistance (e.g., 50 Ohms, although other values are possible) and RX buffer logic 111 and 1:2 de-serializer logic 112 that can convert serial data to parallel data. RX buffer logic can regulate the flow of data Each TX lane 115 to 115N has a high-speed TX driver that can include optional de-emphasis logic (not shown), a 2:1 serializer logic 116 that can convert parallel data to serial data, a programmable pattern generator logic 117 that can be used for initial timing calibrations, and TX buffer logic 118 that can regulate the flow of data. The transmitter and receiver can operate from 1 bit per second (2 bps) to 2 giga bits per seconds (2 gbps). The transmitter and receiver are synchronized to CLK and CLK can be, for example, 1 Hz-1 GHz (1 hertz to 1 gigahertz) frequency. A double data rate protocol (in which data is latched on both rising and falling edges), makes the receiver and transmitter operation range from 2 bps-2 gbps. De-emphasis logic can remove distortion caused by pre-emphasis. Pre-emphasis is a technique that can protect a signal against anticipated noise by boosting frequency range that is susceptible to noise. De-emphasis removes this distortion caused by boosting a frequency range.

The test access port (TAP) 106 can be an industry standard (IEEE 1149.1) unit. The test port uses TAP 106 to access and/or program several registers. A clock buffer 108 is an input buffer with a configurable termination resistor (usually programmed to 50 Ohm by a tester through JTAG/TAP 106). Since the test port can be a double data rate (data is sampled at both rising and falling edges), a 50% duty cycle should be achieved. A clock distribution network can be timed to ensure close to 50% duty cycle. Clock buffer and distribution network logic 8 can be analog circuitry implemented to manage the quality of clock propagation in the design to achieve minimum skew, cross talk, as well as to ensure duty cycle is maintained throughout the network. An RX buffer 111 is an input buffer with a configurable termination resistor (usually programmed to 50 Ohm by a tester through the JTAG/TAP).

A 1:2 de-serializer 112 is used to convert double data rate protocol to single data rate (in which, for example, data is sampled only on rising edge of the clock) and output it to the scan test network. Assuming a highest speed of 1 GHz clock, the test port drives the 2:1 de-serialized data to scan network at 1 GHz on, for example, the rising edge. The scan network can also have 1:N de-serializer 153 to drive data downstream at lower speed to achieve timing convergence by lowering clock frequency but still maintaining the bandwidth. For example, if scan network is only timed to support a 500 MHz clock rate, (153) can be 1:2 de-serializer, if scan network is only timed to support 250 MHz clock rate (153) can be a 1:4 de-serializer and so on. The 1:N serializer 153 converts scan network data to, for example, 1 GHz single data rate and drives it to the test port (for example, if the scan network is timed at 500 MHz, a 2:1 serializer is used, if scan network is timed at 250 MHz, 4:1 serializer is used and so on). A 2:1 serializer converts incoming 1 GHz single data rate signaling to 1 GHz double data rate signaling. A TX buffer 118 can contain a transmitter main driver and de-emphasis driver. The de-emphasis driver can optionally be turned on with chosen de-emphasis values if, for example, turning it on achieves better signal integrity on path to tester with larger signal eye margins.

The DFT interface PHY follows a forwarded clock architecture. Production test system can drive DFT interface clock (CLK 126). The CLK 126 frequency can be anywhere from 1 Hz to 1 GHz. All RX and TX IOs 125M, 125, 127, 127N are synchronous to the CLK 126. For RX operation, data is sent from the test system 130 to the DFT interface and for TX operation data is sent from the DFT interface to the test system 130. The DFT test interface PHY can be one that does not include any logic or state machines that can assist in calibrating resistance or adjusting per pin timings. The test system 130 can include automatic test equipment (ATE) that tests a semiconductor device to determine whether the function, speed, power consumption, reliability, and/or other attributes meet selected standards. Native ATE capability of force current and measuring voltage is used to calibrate RX termination and TX pull-up and pull-down resistors to desired value instead of implementing state machines. Similarly, native ATE capability of timing searches is used to de-skew RX and TX timings with respect to CLK instead of implementing any delay-locked loop (DLL) or de-skewing logic.

The input and output (IO) lanes (which are electrical connection IO bumps, pins, pads, or other structures on a semiconductor device), include RX_LANE[M] 125M, RX_LANE[0] 125, CLK signal 126, TX_LANE[0] 127, TX_LANE[N] 127N. These signal lines can connect to test system 130 for testing of the semiconductor device having the design for test interface. A voltage source 180 can be dedicated to the design for test interface or can be part of a voltage supply to an additional part of the semiconductor device.

For RX operation, each IO's (125 to 125M) bit stream, can be driven on both edges of the CLK signal by the test system (supporting double data rate (DDR) operation), can be de-serialized to 1:2, and can be sent to the test port interface logic 150 as IO RX_DATA_EVEN[LANE] 160 and 162 for lanes 0 to M and IO RX_DATA_ODD[LANE] 161 and 163 for lanes 0 to M at the rising edges of the CLK signal. Test port interface logic 150 sends data (as a bit stream) for IO TX_DATA_EVEN[LANE] 164 and 166 for lanes 0 to N and IO TX_DATA_ODD[LANE] 165 and 167 for lanes 0 to N, to respective TX lanes 115 to 115N on the rising edges of CLK signal. Test port interface logic 150 can interface with the semiconductor device logic. The semiconductor device logic is for performing one or more computing functions. Test port interface logic 150 includes 1:N de-serializer logic 151, 1:N CLK divider logic 152, and N:1 serializer logic 153. Test port interface logic 150 also receives CLKOUT signal 170. Optionally, test port interface logic 150 can include additional frequency step-down logic to drive the semiconductor device scan system if a given semiconductor device cannot converge timing at a speed of 1 GHz for the CLK signal.

The test port operation is fully deterministic and cycle accurate due to test system forwarded clock. Test functions are deterministic in general because the test content available is synchronous—the test system is locked to the CLK signal and delivers known date every cycle. A bit stream starts at an exact time in each CLK cycle. Due to a single ended operation and no encoding involved, a production test system's per pin bandwidth can be maximized as well. Data transmission and receiver efficiency can be up to 100%. Due to source synchronous test system driven clock, the PHY can operate at any clock frequency from 1 Hz to 1 GHz. The available DDR mode of operation means that a supported data rate of anywhere between 2 bps to 2 Gbps may be achieved. Advantageously, the DFT interface can be one that does not employ general purpose IO (GPIO) digital signal lanes, meaning that GPIO design and routing focus can be on the enabling platform and motherboard routing whereas the test port does not require such motherboard or platform breakout as such the IOs can be isolated in a non-congested region of the floorplan/die.

For the DFT interface architecture, automatic resistance calibration and timing calibration can be handled by a production test system (i.e., test system 130, 210, 310). The DFT interface can have a relatively low risk of non-operation at semiconductor device power-on. In addition, the DFT interface can be operated at lower CLK frequencies than the supported 1 GHz at power-on to support diagnostics and further reduce dead-on-arrival risk. A traditional HSIO Phys may take a few days to work. If only the highest data rate is supported (e.g., 2 gbps) and that data rate is not immediately achieved at power-on, this issue can delay testing the rest of the logic on chip, making the semiconductor device a very high risk of being considered non-operational. Since the test port is flexible and can run at any data rate, if a 2 gbps data rate does not work immediately at power-on, the test port can still be enabled at arbitrary low data rate (e.g., 100 mbps) to un-gate rest of the testing at power-on.

The DFT interface can be used during production testing. The DFT interface can be an interface that does not include features such as, for example, an embedded clock architecture, differential signaling, auto resistance, de-skewing and timing calibration. These features are typically used with high speed IO (HSIO) PHYs as these need to operate at high speed on test boards that have different channel quality and lengths. Even if a DFT interface PHY is designed for a specific impedance value (for example 50 Ohm), there can be a wide variation of actual silicon value due to process variation. To resolve this in a different system, a complex auto calibration scheme using an external precision resistor could be needed.

The DFT interface can avoid the foregoing complexities. Though production test system can have limitations including low tolerance for non-deterministic operations compared to a real system, it can have advantages as well. First, a production test system supports a precision direct current (DC) measurement circuit (that can force voltage and measuring current on a given pin and vice-versa) on each test system channel which can be used to measure device resistances. Production test system can also drive or strobe with precisely programmed voltages and run fine timing searches. These features are typically not feasible in a non-test system environment. It can be the case that the semiconductor device test interface is used during production testing on production test system and there is no test interface usage outside of a manufacturing environment.

Traditional high-speed IO PHYs use differential signaling which makes effective bandwidth per pin, half of the actual data rate, since differential pairs (RXP/RXN, TXP/TXN) are used. There can be an additional 20% bandwidth reduction due to 8b10b encoding where each 8-bits are encoded to 10-bits to make clock recovery possible. This means that effective bandwidth achieved is ˜40% of data rate for the given pin. For example, if a traditional high-speed IO PHY architecture is used instead of the DFT interface (assuming the non-determinism problem is solved), bandwidth per pin would be about 40% of the test system driven bandwidth. If the test system is driving 2 Gbps data rate on twice as many pins with data stream 8b/10b encoded, effective data rate would only be 800 Mbps per pin.

Traditional High Speed Serial IO PHYs can only operate at specific frequencies. For example, a PCI Express PHY can operate at 2.5/5/10/16/32 Gbps operation only. In the production environment, testing needs to work at any data rate. For example, it is possible that a product die level test environment can only support 1-Gbps max operation hence the PHY must be able to support this. Silicon debug heavily relies on flexibility to check timing margins with these arbitrary rates. The DFT interface's ability to run at any arbitrary rate allows flexible usage across multiple testing phases and test platforms.

The test ports of the DFT interface can be accessible at both die level and package level, and testing for a given semiconductor device can be accomplished with the same IO pins and interface, at the die level or the package level. The test system view of the semiconductor device as well as test modes required to access a given semiconductor device can be the same at both die and package level testing. The test system can have direct access to a given semiconductor device at the package level, which means that test IO signals from a first semiconductor device are not routed through a second semiconductor device. Since each semiconductor device can be connected to a test system directly through the DFT interface, semiconductor devices can be tested in parallel. The test application mechanism can be the same at both the die and package level testing, and the same test vectors can be used at both die and package level testing.

FIG. 2 illustrates a package-level semiconductor device testing system. The semiconductor device testing system includes a test board 205 and the semiconductor device test system 210. The test board 205 can be a printed circuit board that provides a mechanical and electrical interface that connects a device under test (DUT) to test system 210. A device under test (DUT) can be connected to the test board 205 for production testing. The test board 205 can also include power and reset interconnection points for a semiconductor package 215 (i.e., a DUT). Interconnection points can be pins, pads, balls, bumps, or have other shapes that mate with interconnection points of the semiconductor package 215. The test system 210 can include ATE that tests a semiconductor device to determine whether the function, speed, power consumption, reliability, and/or other attributes meet selected standards.

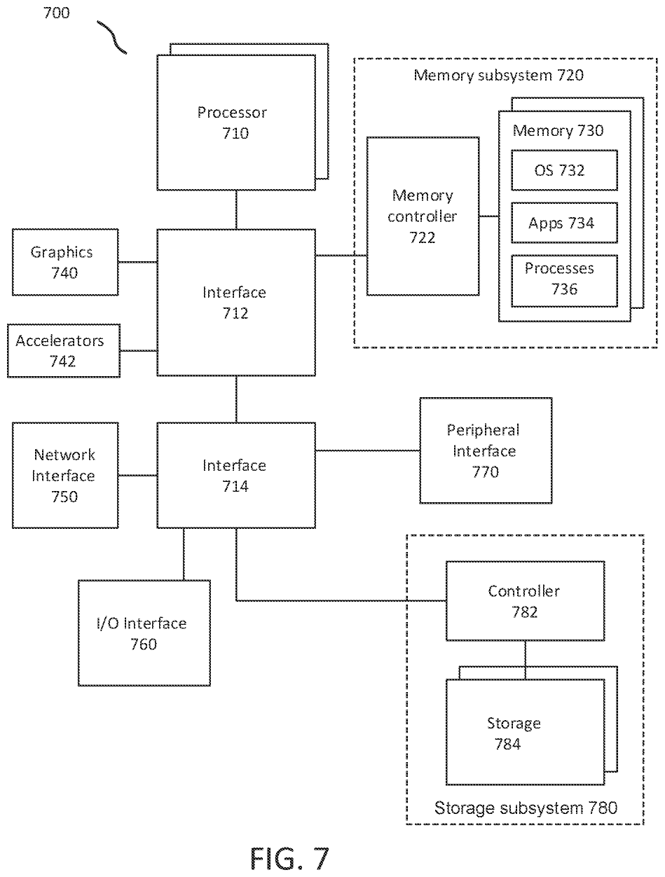

In FIG. 2, the package-level semiconductor device testing system is illustrated with a semiconductor package 215 that includes semiconductor devices 220 and IO chip 221. Other numbers and arrangements of semiconductor devices 220 and 221 in semiconductor package 215 are possible. Additionally, semiconductor devices 220 can be any number and/or combination of microprocessors, CPUs (central processing units), GPUs (graphics processing units), processing cores, chiplets, system on a chips, other processing hardware, a combination of processors or processing cores or chiplets, programmable general-purpose or special-purpose microprocessors, accelerators, DSPs, IO management devices, programmable controllers, ASICs, programmable logic devices (PLDs), high bandwidth memory (HBM), and/or other memory devices. The semiconductor device package 215 can be a heterogeneous package that incorporates different types of semiconductor devices into one package. The semiconductor devices 220 can be any of the chips, for example, described herein with respect to FIG. 7. Chiplets can be processing cores or processors. The semiconductor devices 221 and 221 include design for test (DFT) interfaces. The design for test (DFT) interfaces are coupled to test port IO signal lines 225 within semiconductor package 215. Test port IO signal lines 225 include RX_LANE[M] 125M, RX_LANE[0] 125, CLK signal 126, TX_LANE[0] 127, TX_LANE[N] 127N of FIG. 1 that can connect the semiconductor devices 220 and 221, to test system 210 through test board 205. Semiconductor devices 220 include a test port physical layer (PHY) 101 that includes a common lane 105, one or more RX (receiver) 110 to 110M, and one or more TX (transmitter) lanes 115 to 115N (as described herein and with respect to FIGS. 1, 3-5). Test port IO signal lines 225 are shown in the semiconductor package 215 and are connected through test board 205 to semiconductor device test system 210. Test board 205 also includes test port IO signal lines 225 and interconnection points that mate with interconnection points in the semiconductor package 215 for the test port IO signal lines 225 in the semiconductor package 215. Test board 205 connects signal lines to the semiconductor device test system 210 through interconnections.

The test board 205 can also include high speed serial IO connection(s) 235, low speed serial IO connections 237, loop backs 240 for some TX and/or RX signals, and/or double data rate synchronous dynamic random-access memory (DDR SRAM) and/or low-power DDR SRAM connections 245. Semiconductor package 215 can also optionally include universal chiplet interconnect express (UCIe) interconnections 230 between semiconductor chips 220 and 221.

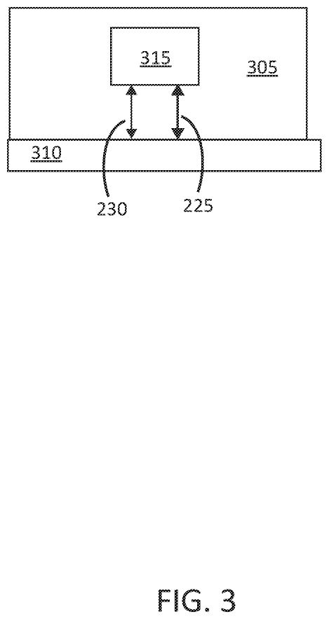

FIG. 3 shows a chip-level semiconductor device testing system. The semiconductor device testing system includes a test board 305 and the semiconductor device test system 310. The test board 305 can be a printed circuit board that provides a mechanical and electrical interface that connects a DUT to test system 310. A DUT can be connected to the test board 305 for production testing. The test board 305 can also include power and reset interconnection points for a semiconductor device 315 (i.e., the DUT in this example). Interconnection points can be pins, pads, balls, bumps, or have other shapes that mate with interconnection points of the semiconductor device 315. Interconnection points of semiconductor device 315 can also be pins, pads, balls, bumps, or have other shapes. Where the numbering of parts of FIGS. 2 and 3 are the same, the descriptions herein for the same-numbered parts for FIG. 2 can be used for FIG. 3. Test port IO signal lines 225 in the test board 305 are connected to a DFT interface on semiconductor device 315. Test board 305 connects signal lines to the semiconductor device test system 310 through interconnections. The test system 310 can include ATE that tests a semiconductor device to determine whether the function, speed, power consumption, reliability, and/or other attributes meet selected standards.

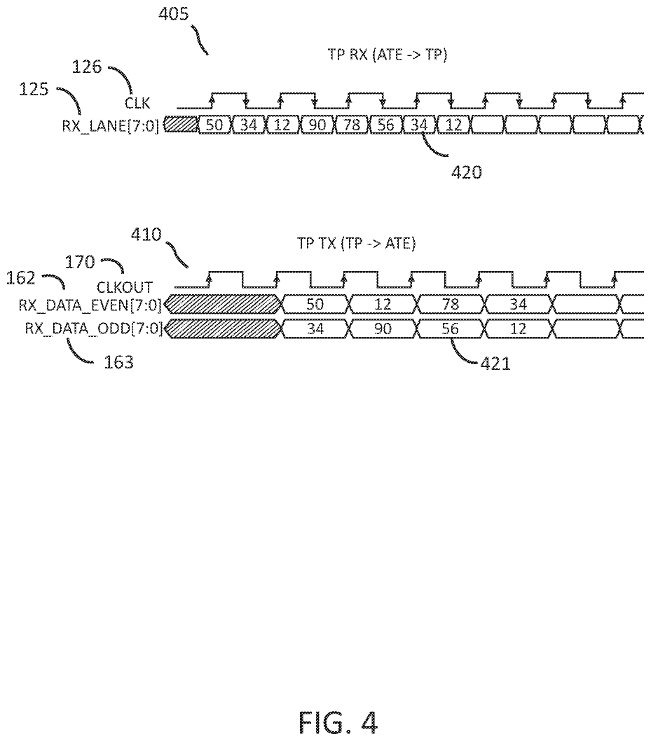

FIG. 4 provides example waveforms for DFT interface operation assuming 8 RX and 8 TX lanes. Waveforms 405 show test port RX operation where signals are driven from automatic testing equipment (ATE) to the test port (TP). Waveforms 410 show test port TX operation, where signals are driven from the test port (TP) to the ATE. TX and RX data are driven on both rising and falling edge of the clock (CLK) 126 by the ATE, supporting double data rate (DDR) operation. Bit stream packets of data 420 and 421 are numbered in order to show system operation. Where the numbering of parts of FIGS. 1 and 4 are the same, the descriptions herein for the same-numbered parts for FIG. 1 can be used for FIG. 4. Test port input lanes include RX_LANE[LANE] 125 and CLK signal 126. Test port interface logic sends data to the ATE on RX_DATA_EVEN[LANE] 162 and IO RX_DATA_ODD[LANE] 163 on CLKOUT signal 170.

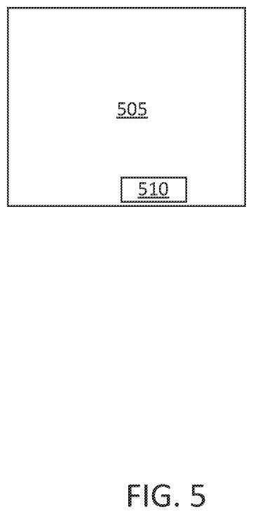

FIG. 5 provides a diagram of a semiconductor device 505 having a DFT interface 510. DFT interface 510 is described herein and with respect to FIG. 1. The DFT interface includes, for example, the test port physical layer (PHY) 101 and associated features, and the test port interface logic 150 and associated features of FIG. 1. Semiconductor device 505 includes logic for performing one or more computing functions, and can be, for example, a microprocessor, CPU (central processing unit), GPU (graphics processing unit), processing core, chiplet, system on a chip, programmable general-purpose or special-purpose microprocessor, accelerator, DSP, IO management device, programmable controller, ASIC, programmable logic device (PLD), high bandwidth memory (HBM), or other memory devices. Chiplets can be processor cores or processors.

Due to manufacturing process variations, RX termination and TX pull-up and pull-down resistance values can deviate from a desired 50 Ohm value and can therefore need calibration. The TP PHY can use a production test system's native DC measurement capabilities to measure RX termination and TX pull up/down resistances to calibrate them to 50 Ohm instead of requiring auto calibration state machines. These resistances can be programmable by driving specific codes though a common lane TAP port. A binary search can be performed by a test system by driving a known code and then measuring the resistance value for that code. Once this test system operation is complete, the DUT can have the optimal code for each resistance to achieve, for example, 50 Ohm. Codes are the values being programmed to RX termination and TX pull up/down resistor settings.

The TP can use the test system's timing search and programmable voltage capabilities for CLK duty cycle calibration. For this, a TX pattern generator is loaded with a known pattern and kicked off using the test system driven CLK as a clock source. The test system then runs timing searches on the TX driven bit stream to measure duty cycle as seen by the TP PHY. For the first search, default values of CLK high input level (VIH) and low input level (VIL) are chosen. Then the value of VIH and VIL is updated, and the search is done again. After this procedure, the test system can have optimized VIH/VIL settings for close to a 50/50 duty cycle after the CLK receiver.

Once resistance and CLK duty cycle calibrations are done, TP PHY's far-end loopback mode (RX->TX loopback) capability is used for final RX timing (tester driver) and TX (tester strobe) calibration. After this method, the tester has optimal drive and strobe timing values for each lane and the TP PHY is ready for content enabling.

The PHY 101 of FIG. 1 can have a dedicated power supply that is isolated from the semiconductor device's power delivery network. A PHY 101 that has a dedicated power supply can be tied to ground on end user platforms so that the test only PHY 101 does not contribute to any active/dynamic power leakage during end use. There can be zero power penalty associated with PHY 101 that has a dedicated power supply in non-manufacturing use cases. Additionally, with a dedicated power supply to PHY 101, manufacturing test use cases can run voltage searches on a DUT without impacting PHY performance.

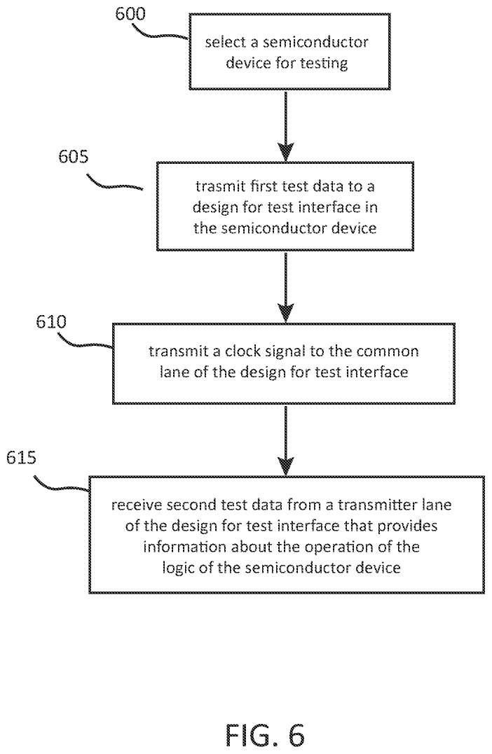

FIG. 6 diagrams a method for testing a semiconductor device. In FIG. 6, a semiconductor device is selected for testing 600. The semiconductor device can be in die form or can be a packaged semiconductor device. The package can comprise multiple semiconductor devices and the multiple semiconductor devices can be tested in parallel, so that multiple semiconductor devices within the package are selected for testing in a testing run. The semiconductor device (or devices) each include a design for test interface. The design for test interface can be the design for test interface as described herein and with respect to FIGS. 1, 4, and 5. If the semiconductor device is unpackaged, the test assembly can be the assembly of FIG. 3. If the semiconductor device(s) are packaged, the test assembly can be the assembly of FIG. 4. Test data is transmitted to the design for test interface 605. The design for test interface can include a transmitter lane 115, a common lane 105, and a receiver lane 110, and test port interface logic 150. A clock signal is transmitted to the common lane 610. Second test data is received from the transmitter lane of the design for test interface 615. The second test data provides information about the operation of the logic of the semiconductor device. Operations 600, 605, 610, and/or 615 can be performed by a semiconductor device test system, such as automatic test equipment (ATE).

FIG. 7 depicts an example computing system. The computing system can be a system used for a semiconductor test system. For example, instructions for operating automatic test equipment (ATE), or for performing one or more aspects of the process described in FIG. 6 can be stored and/or run on the computing system. A computing system 700 can include more, different, or fewer features than the ones described with respect to FIG. 7.

Computing system 700 includes processor 710, which provides processing, operation management, and execution of instructions for system 700. Processor 710 can include any type of microprocessor, CPU (central processing unit), GPU (graphics processing unit), processing core, or other processing hardware to provide processing for system 700, or a combination of processors or processing cores. Processor 710 controls the overall operation of system 700, and can be or include, one or more programmable general-purpose or special-purpose microprocessors, DSPs, programmable controllers, ASICs, programmable logic devices (PLDs), or the like, or a combination of such devices.

In one example, system 700 includes interface 712 coupled to processor 710, which can represent a higher speed interface or a high throughput interface for system components needing higher bandwidth connections, such as memory subsystem 720 or graphics interface components 740, and/or accelerators 742. Interface 712 represents an interface circuit, which can be a standalone component or integrated onto a processor die. Where present, graphics interface 740 interfaces to graphics components for providing a visual display to a user of system 700. In one example, the display can include a touchscreen display.

Accelerators 742 can be a fixed function or programmable offload engine that can be accessed or used by a processor 710. For example, an accelerator among accelerators 742 can provide data compression (DC) capability, cryptography services such as public key encryption (PKE), cipher, hash/authentication capabilities, decryption, or other capabilities or services. In some cases, accelerators 742 can be integrated into a CPU socket (e.g., a connector to a motherboard (or circuit board, printed circuit board, mainboard, system board, or logic board) that includes a CPU and provides an electrical interface with the CPU). For example, accelerators 742 can include a single or multi-core processor, graphics processing unit, logical execution unit single or multi-level cache, functional units usable to independently execute programs or threads, application specific integrated circuits (ASICs), neural network processors (NNPs), programmable control logic, and programmable processing elements such as field programmable gate arrays (FPGAs) or programmable logic devices (PLDs). Accelerators 742 can provide multiple neural networks, CPUs, processor cores, general purpose graphics processing units, or graphics processing units can be made available for use by artificial intelligence (AI) or machine learning (ML) models.

Memory subsystem 720 represents the main memory of system 700 and provides storage for code to be executed by processor 710, or data values to be used in executing a routine. Memory subsystem 720 can include one or more memory devices 730 such as read-only memory (ROM), flash memory, one or more varieties of random access memory (RAM) such as static RAM (SRAM), dynamic RAM (DRAM), synchronous DRAM (SDRAM) and/or or other memory devices, or a combination of such devices. Memory 730 stores and hosts, among other things, operating system (OS) 732 that provides a software platform for execution of instructions in system 700, and stores and hosts applications 734 and processes 736. In one example, memory subsystem 720 includes memory controller 722, which is a memory controller to generate and issue commands to memory 730. The memory controller 722 can be a physical part of processor 710 or a physical part of interface 712. For example, memory controller 722 can be an integrated memory controller, integrated onto a circuit within processor 710.

System 700 can also optionally include one or more buses or bus systems between devices, such memory buses, graphics buses, and/or interface buses. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a peripheral component interface (PCI) or PCI express (PCIe) bus, a Hyper Transport or industry standard architecture (ISA) bus, a small computer system interface (SCSI) bus, a universal serial bus (USB), or a Firewire bus.

In one example, system 700 includes interface 714, which can be coupled to interface 712. In one example, interface 714 represents an interface circuit, which can include standalone components and integrated circuitry. In one example, user interface components or peripheral components, or both, couple to interface 714. Network interface 750 provides system 700 the ability to communicate with remote devices (e.g., servers or other computing devices) over one or more networks. Network interface 750 can include an Ethernet adapter, wireless interconnection components, cellular network interconnection components, USB, or other wired or wireless standards-based or proprietary interfaces. Network interface 750 can transmit data to a device that is in the same data center or rack or a remote device, which can include sending data stored in memory.

Some examples of network interface 750 are part of an infrastructure processing unit (IPU) or data processing unit (DPU), or used by an IPU or DPU. An xPU can refer at least to an IPU, DPU, GPU, GPGPU (general purpose computing on graphics processing units), or other processing units (e.g., accelerator devices). An IPU or DPU can include a network interface with one or more programmable pipelines or fixed function processors to perform offload of operations that can have been performed by a CPU. The IPU or DPU can include one or more memory devices.

In one example, system 700 includes one or more input/output (I/O) interface(s) 760. I/O interface 760 can include one or more interface components through which a user interacts with system 700 (e.g., audio, alphanumeric, tactile/touch, or other interfacing). Peripheral interface 770 can include additional types of hardware interfaces, such as, for example, interfaces to semiconductor fabrication unit and/or electrostatic charge management devices.

In one example, system 700 includes storage subsystem 780. Storage subsystem 780 includes storage device(s) 784, which can be or include any conventional medium for storing data in a nonvolatile manner, such as one or more magnetic, solid state, and/or optical based disks. Storage 784 can be generically considered to be a “memory,” although memory 730 is typically the executing or operating memory to provide instructions to processor 710. Whereas storage 784 is nonvolatile, memory 730 can include volatile memory (e.g., the value or state of the data is indeterminate if power is interrupted to system 700). In one example, storage subsystem 780 includes controller 782 to interface with storage 784. In one example controller 782 is a physical part of interface 712 or processor 710 or can include circuits or logic in both processor 710 and interface 714.

A power source (not depicted) provides power to the components of system 700. More specifically, power source typically interfaces to one or multiple power supplies in system 700 to provide power to the components of system 700.

Exemplary systems may be implemented in various types of computing, smart phones, tablets, personal computers, and networking unit, such as switches, routers, racks, and blade servers such as those employed in a data center and/or server farm environment.

### EXAMPLES

A semiconductor device can comprise: logic for performing one or more computing functions; and a design for test interface, wherein the design for test interface comprises: a physical layer that comprises one or more receiver lanes wherein the one or more receive lanes comprise receiver buffer logic, one or more transmitter lanes wherein the one or more transmitter lanes comprise a transmitter buffer logic, and a common lane, wherein the common lane comprises clock buffer logic and network distribution logic; wherein the design for test interface is coupled to the logic for performing one or more computing functions and wherein the design for test interface is capable of being coupled to a semiconductor device test system. The design for test interface can also comprise test port interface logic that is capable of interfacing with the logic for performing one or more computing functions. The design for test interface can also comprise a test port interface that comprises, serializer logic, de-serializer logic, and clock divider logic. The one or more receiver lanes can also comprise de-serializer logic. The one or more transmitter lanes can also comprise serializer logic. The one or more transmitter lanes can also comprise pattern generator logic. The design for test interface can have a dedicated power supply.

A semiconductor assembly can comprise: a semiconductor package substrate wherein the semiconductor package substrate comprises a test port input output (IO) signal line wherein the test port IO signal line comprises a transmitter line, a clock signal line, and a receiver line; and a semiconductor device wherein the semiconductor device comprises a design for test interface, wherein the design for test interface comprises a transmitter lane, a common lane, and a receiver lane, and wherein the test port IO signal line is operably coupled to the design for test interface. The semiconductor assembly can additionally comprise three or more processor chiplets, wherein each of the three or more processor chiplets comprise a design for test interface; and wherein each of the three or more processor chiplets are operably coupled to a separate test port IO signal line that is in the semiconductor package substrate. The semiconductor package substrate can comprise an interconnect region that is able to couple semiconductor test equipment to the test port IO signal line. The design for test interface can also comprise a test port interface that comprises de-serializer logic and clock divider logic. The common lane can comprise clock buffer logic and network distribution logic. The design for test interface can comprise a plurality of transmitter lanes and wherein the signal line comprises a plurality of transmitter lines. The design for test interface can have a dedicated power supply.

A method for testing a semiconductor device can comprise: transmitting first test data to a design for test interface in a semiconductor device, wherein the semiconductor device comprises logic for performing one or more computing functions, wherein the design for test interface comprises a transmitter lane, a common lane, and a receiver lane; transmitting a clock signal to the common lane; and receiving second test data from the transmitter lane of the design for test interface wherein the second test data provides information about an operation of the logic of the semiconductor device. The semiconductor device can be a packaged semiconductor device and a testing system transmits first test data through a package substrate to the design for test interface of the semiconductor device. Transmitting first data can occur at a data rate of between 2 bps to 2 Gbps. Transmitting first data can occur a clock frequency between 1 Hz and 1 GHz. The direct current (DC) measurement capabilities of a semiconductor device test system can be used to calibrate a receiver termination resistance of the design for test interface. The common lane can comprise clock buffer logic and network distribution logic.

Besides what is described herein, various modifications can be made to what is disclosed without departing from the scope. Therefore, the illustrations and examples herein should be construed in an illustrative, and not a restrictive sense.

What is claimed is:

1. A semiconductor device comprising:
logic for performing one or more computing functions; and
a design for test interface, wherein the design for test interface comprises:
a physical layer that comprises one or more receiver lanes wherein the one or more receive lanes comprise receiver buffer logic, one or more transmitter lanes wherein the one or more transmitter lanes comprise a transmitter buffer logic, and a common lane, wherein the common lane comprises clock buffer logic and network distribution logic;
wherein the design for test interface is coupled to the logic for performing one or more computing functions and wherein the design for test interface is capable of being coupled to a semiconductor device test system.

2. The semiconductor device of claim 1, wherein the design for test interface also comprises test port interface logic that is capable of interfacing with the logic for performing one or more computing functions.

3. The semiconductor device of claim 1 wherein the design for test interface also comprises a test port interface that comprises, serializer logic, de-serializer logic, and clock divider logic.

4. The semiconductor device of claim 1 wherein the one or more receiver lanes also comprise de-serializer logic.

5. The semiconductor device of claim 1 wherein the one or more transmitter lanes also comprise serializer logic.

6. The semiconductor device of claim 1 wherein the one or more transmitter lanes also comprise pattern generator logic.

7. The semiconductor device of claim 1 wherein the design for test interface has a dedicated power supply.

8. A semiconductor assembly comprising:
a semiconductor package substrate wherein the semiconductor package substrate comprises a test port input output (IO) signal line wherein the test port IO signal line comprises a transmitter line, a clock signal line, and a receiver line; and
a semiconductor device wherein the semiconductor device comprises a design for test interface, wherein the design for test interface comprises a transmitter lane, a common lane, and a receiver lane, and wherein the test port IO signal line is operably coupled to the design for test interface.

9. The semiconductor assembly of claim 8, additionally comprising three or more processor chiplets, wherein each of the three or more processor chiplets comprise a design for test interface; and wherein each of the three or more processor chiplets are operably coupled to a separate test port IO signal line that is in the semiconductor package substrate.

10. The semiconductor assembly of claim 8, wherein the semiconductor package substrate comprises an interconnect region that is able to couple semiconductor test equipment to the test port IO signal line.

11. The semiconductor assembly of claim 8, wherein the design for test interface also comprises a test port interface that comprises de-serializer logic and clock divider logic.

12. The semiconductor assembly of claim 8, wherein the common lane comprises clock buffer logic and network distribution logic.

13. The semiconductor assembly of claim 8, wherein the design for test interface comprises a plurality of transmitter lanes and wherein the signal line comprises a plurality of transmitter lines.

14. The semiconductor assembly of claim 8, wherein the design for test interface has a dedicated power supply.

15. A method for testing a semiconductor device comprising:
transmitting first test data to a design for test interface in a semiconductor device, wherein the semiconductor device comprises logic for performing one or more computing functions, wherein the design for test interface comprises a transmitter lane, a common lane, and a receiver lane;
transmitting a clock signal to the common lane; and
receiving second test data from the transmitter lane of the design for test interface wherein the second test data provides information about an operation of the logic of the semiconductor device.

16. The method of claim 15, wherein the semiconductor device is a packaged semiconductor device and a testing system transmits first test data through a package substrate to the design for test interface of the semiconductor device.

17. The method of claim 15, wherein transmitting first data occurs at a data rate of between 2 bps to 2 Gbps.

18. The method of claim 15, wherein transmitting first data occurs a clock frequency between 1 Hz and 1 GHz.

19. The method of claim 15, wherein direct current (DC) measurement capabilities of a semiconductor device test system are used to calibrate a receiver termination resistance of the design for test interface.

20. The method of claim 15, wherein the common lane comprises clock buffer logic and network distribution logic.
